(19) United States
(12) Patent Application Publication
(10) Pub. No.: US 2009/0001567 A1
(43) Pub. Date: Jan. 1, 2009

(54) IC chip with finger-like bumps

(75) Inventors: Ho-Cheng Shih, Taipei City (TW); Chun-Yuan Wang, Taipei City (TW); J-Fang Cheng, Taipei City (TW); Chiung-Lin Wang, Taipei City (TW); Suen-Wen Chung, Taipei-City (TW)

Correspondence Address: Joe McKinney Muncy, PO Box 1364, Fairfax, VA, 22038-1364, US

(73) Assignee: ULTRA CHIP, INC.

(21) Appl. No.: 11/819,460

(22) Filed: Jun. 27, 2007

(51) Int. Cl. H01L 23/498

(52) U.S. Cl. 257/737; 257/E23.067

(57) ABSTRACT

A bumped chip has a plurality of finger-like bumps bonded on multiple openings of a chip. The chip primarily comprises a plurality of bonding pads and a passivation layer having a plurality of opening thereon. In one embodiment, the openings on each bonding pad are plural and disposed in linear, in parallel, or in an array. The finger-like bumps are protrusively disposed on the chip and each has a bump core and an extension finger. The bump cores are disposed within the corresponding bonding pads and cover the openings, and the extension fingers are disposed outside the corresponding bonding pads to maintain the bonding strengths of the bumps even at fine pitches. In an embodiment, the extension fingers overlap at least a trace of the chip.

### FIELD OF THE INVENTION

The present invention relates to a bumped semiconductor chip, especially, to a bumped chip with finger-like bumps bonded on multiple openings.

### BACKGROUND OF THE INVENTION

Metal bumps such as gold bumps are disposed on the bonding pads of an IC chip as electrical connections for Chip-On-Glass (COG) and Chip-On-Film (COF). The electrical signals of the IC chip are sent from the bumps through the traces on the substrate to the electronic devices such as liquid crystal displays. As the requirements of the better image qualities and higher resolutions, the bumps on an IC chip have relatively increased. Furthermore, the miniaturization requirement of electronic devices, the IC chip becomes more complicated in functions and smaller in dimension leading to smaller bump pitches. As shown in FIGS. 1 and 2, a conventional bumped chip 100 primarily comprises a chip 110 and a plurality of bumps 120 and 140. The chip 110 has an active surface 111 and a passivation layer 113 thereon where a plurality of bonding pads 112 are formed on the active surface 111. The passivation layer 113 formed on the active surface 111 has a plurality of openings 114 to expose the bonding pads 112. As shown in FIGS. 3 and 4, each opening 114 is aligned to the center of the bonding pad 112 and the dimensions of the openings 114 are smaller than the one of the bonding pads 112. The chip 110 has a plurality of traces 116 covered by the passivation layer 113 which are adjacent to the bonding pads 112 and are electrically connected to the IC active area of the chip 110. Normally, the lengths of the bumps 120 will not exceed twice of the widths of the bumps 120 and the bumps 120 will not pass over the traces 116. As shown in FIG. 3, the bumps 120 are disposed in the openings 114 of the passivation layer 113 and extruded from the active surface 111 of the chip 110 where the bumps 120 in high-density arrangement are close to the edge 115 of the chip 110 as terminals, as shown in FIGS. 1 and 2. As shown in FIG. 3 again, an Under-Bump-Metallurgy (UBM) layer 130 is aligned with the openings 114 and formed between the passivation layer 113 and the bumps 120 to electrically connect to the bonding pads 112 to enhance the adhesion and reliability of the bumps 112. As shown in FIGS. 1 and 2, the bumps 140 are disposed at one side of the active surface 111 of the chip 110 as input terminals, the bumps 120 at the opposing side 115 as output terminals. Normally, the density of bumps 120 disposed at the corresponding side 115 is relatively higher than the one of the bumps 140. In order to increase the density of the bumps 120 and keep a minimum spacing, the dimensions of the bumps 120 are correspondingly shrunk leading to weaker bumping strengths.

### SUMMARY OF THE INVENTION

The main purpose of the present invention is to provide a bumped chip with finger-like bumps without increasing the chip dimensions nor decreasing the bumping strengths to meet the requirement of high-density bumps.

The second purpose of the present invention is to provide a bumped chip with finger-like bumps bonded on multiple openings to increase the density of bumps and to increase the anti-cracking properties at the interfaces between bumps and the bonding pads and to reduce the roughness on the top of the bumps to increase the bonding strengths.

The third purpose of the present invention is to provide a bumped chip with finger-like bumps bonded on multiple openings to extend the bumps into the IC active area of the chip.

In the present embodiment of the present invention, a bumped chip with finger-like bumps bonded on multiple openings, primarily comprises a chip and a plurality of finger-like bumps. The chip has an active surface, a plurality of bonding pads disposed on the active surface, and a passivation layer with a plurality of openings corresponding to the bonding pads. The total dimensions of the openings on each bonding pad are smaller than the corresponding one of the bonding pads to partially expose the bonding pads. The finger-like bumps are protrusively disposed on the chip. Each finger-like bump has a bump core and an extension finger where the footprints of the bump cores are disposed within the bonding pads and larger than the openings, and the footprints of the extension fingers disposed outside the bonding pads. In one embodiment, the extension fingers pass over at least a trace.

### DESCRIPTION OF THE DRAWINGS

FIG. 1 shows a cross-sectional view of a conventional bumped chip.

FIG. 2 shows a partial top view of a conventional bumped chip.

FIG. 3 shows a cross-sectional view of a bump of a conventional bumped chip.

FIG. 4 shows an enlarged top view of a conventional bumped chip.

FIG. 5 shows a cross-sectional view of a bumped chip with finger-like bumps according to the first embodiment of the present invention.

FIG. 6 shows a partial top view of a bumped chip according to the first embodiment of the present invention.

FIG. 7 shows a top view of a finger-like bump according to the first embodiment of the present invention.

FIG. 8 shows a partial cross-sectional view of a finger-like bump bonded to a substrate according to the first embodiment of the present invention.

FIG. 9 shows a partial top view of a bumped chip with finger-like bumps according to the second embodiment of the present invention.

FIG. 10 shows an enlarged top view of a bumped chip according to the second embodiment of the present invention.

FIG. 11 shows a cross-sectional view of a finger-like bump according to the second embodiment of the present invention.

FIG. 12 shows a cross-sectional view of a finger-like bump bonded to a substrate according to the second embodiment of the present invention.

FIG. 13A to FIG. 13L show different top views of finger-like bumps bonded on different openings of chips according to the second embodiment of the present invention.

FIG. 14 shows a partial top view of a bumped chip with finger-like bumps according to the third embodiment of the present invention.

FIG. 15 shows an enlarged top view of a finger-like bump of a bumped chip according to the third embodiment of the present invention.

FIG. 16A to FIG. 16B show different top views of finger-like bumps bonded on different openings of chips according to the third embodiment of the present invention.

FIG. 17 shows an enlarged partial cross-sectional view of a finger-like bump of a bumped chip bonded to a substrate by ACF according to the third embodiment of the present invention.

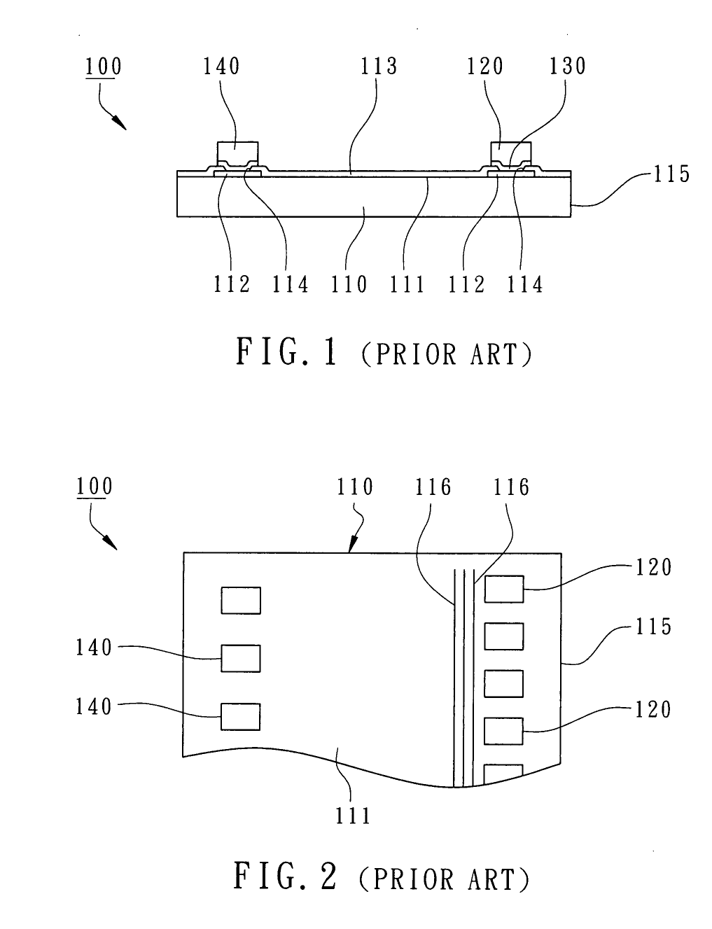

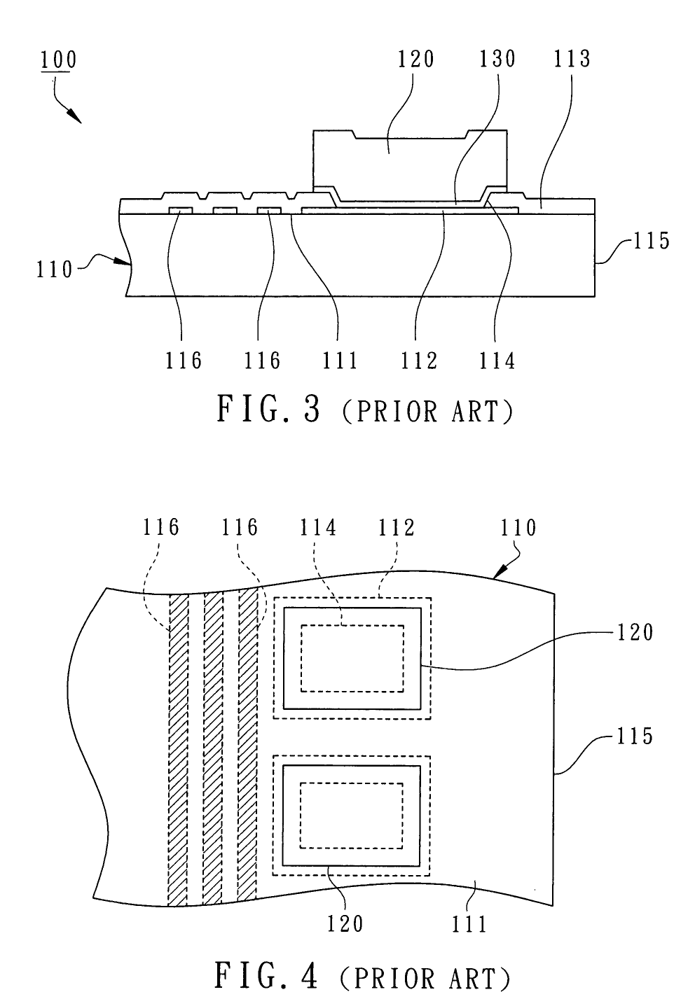

### DETAIL DESCRIPTION OF THE INVENTION

Please refer to the attached drawings, the present invention will be described by means of embodiments below.

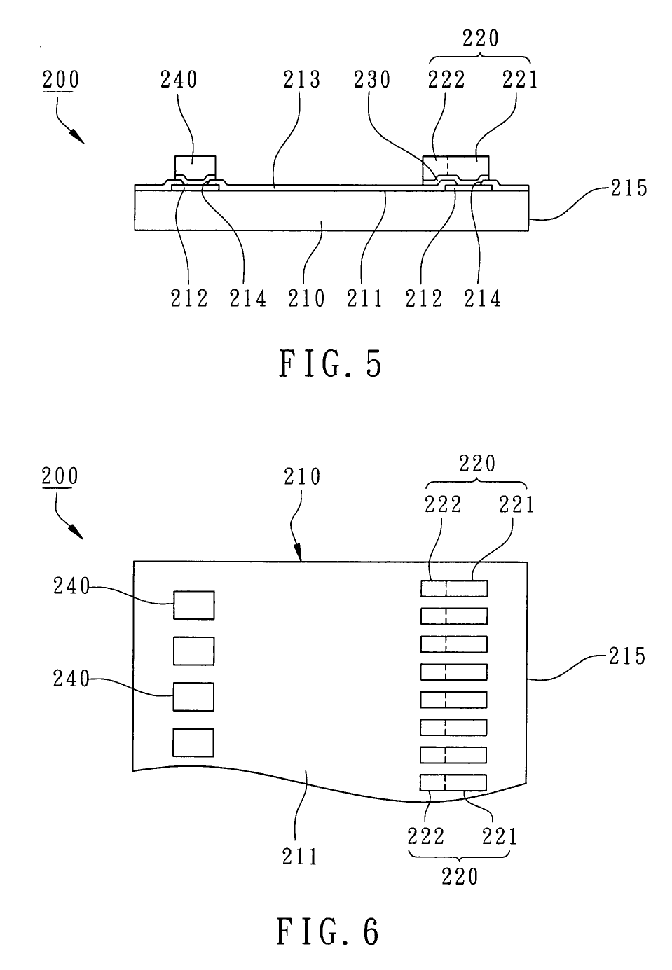

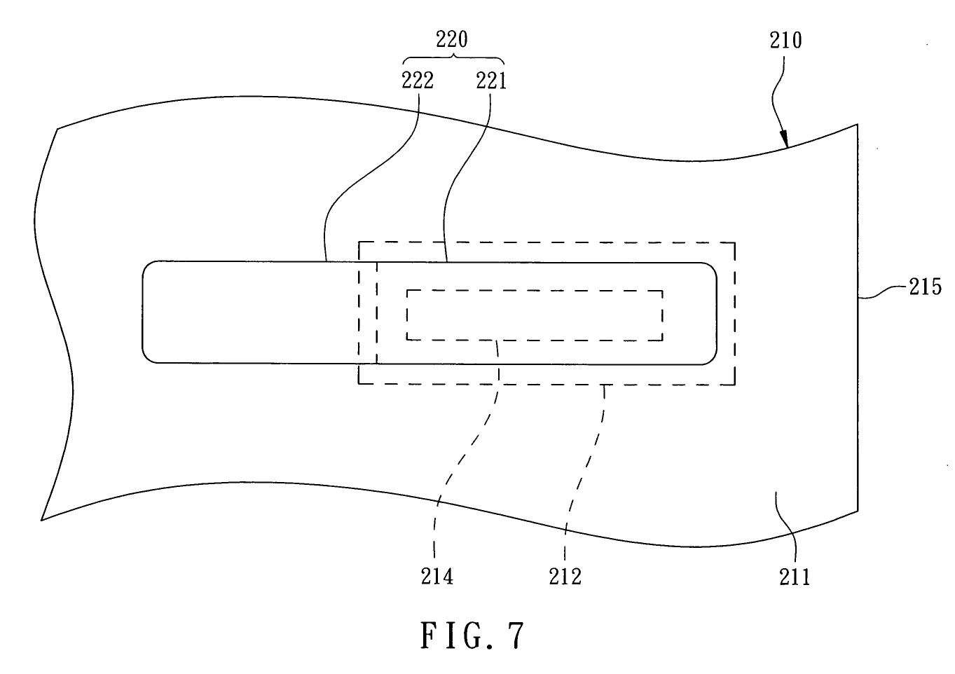

According to the first embodiment of the present invention, as shown in FIGS. 5 to 8, a bumped chip 200 primarily comprises a chip 210 and a plurality of finger-like bumps 220. In this embodiment, as shown in FIG. 6, the bumped chip 200 further comprises a plurality of regular bumps 240. As shown in FIG. 5, the chip 210 has an active surface 211 and a plurality of bonding pads 212 formed on the active surface 211. In the present embodiment, the bonding pads 212 are aluminum (Al) pads. As shown in FIG. 7, the bonding pads 212 are rectangular with the widths and the lengths ranged from 10 μm to 100 μm and from 50 μm and 200 μm, respectively, and with the thickness of the bonding pads 212 less than 1.5 μm.

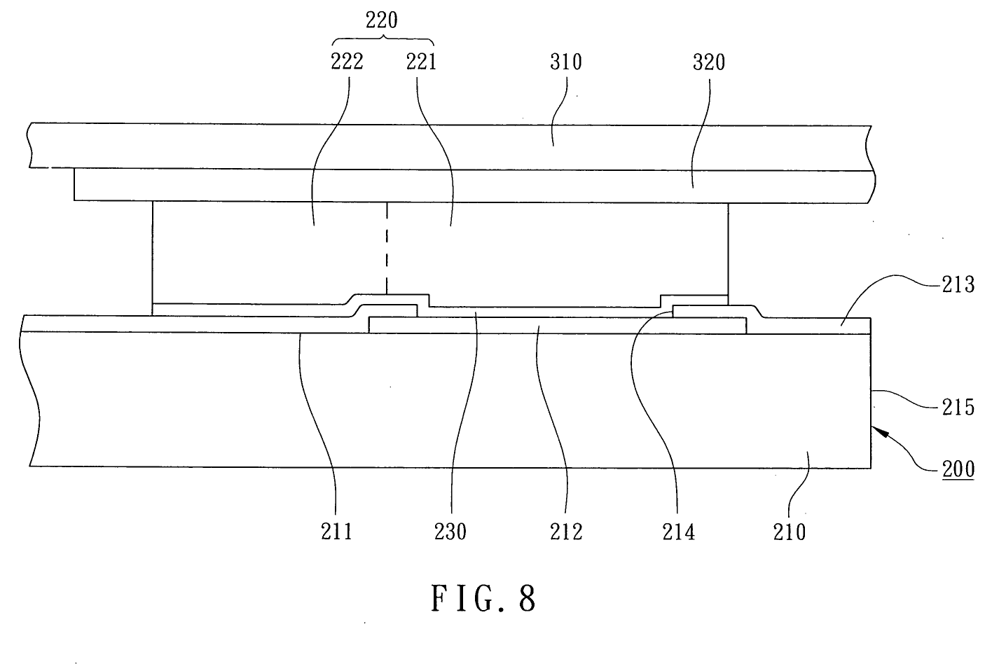

As shown in FIGS. 5 and 8, the chip 210 further has a passivation layer 213 with a plurality of openings 214 corresponding to the bonding pads 212 to partially expose the bonding pads 212. As shown in FIG. 7, the openings 214 are formed as narrow slots with a width less than 12 μm and with a length less than 120 μm. The dimension of each opening 214 is smaller than the one of the bonding pad 212 so that the bonding pad 212 can partially be exposed from the opening 214. Normally, the passivation layer 213 is chosen from PSG, PI or BCB with thickness not greater than 3 μm.

As shown in FIG. 5, the finger-like bumps 220 are protrusively disposed on the active surface 211 of the chip 210 where each finger-like bump 220 has a bump core 221 and an extension finger 222. As shown in FIG. 6, the finger-like bump 220 can be designed as parallel strips where the shape of the bump core 221 is the same as the one of a conventional bump or proportionally shrunk. As shown in FIGS. 7 and 8, the bump core 221 is aligned with the corresponding bonding pad 212 and has a footprint located within the corresponding bonding pad 212 and larger than the opening 214. The width of the bump core 221 is not greater than 20 μm and the length of the bump core 221 ranges from 50 Hμto 130 μm and the total length of the gold bump 220 is less than 250 μm. In the present embodiment, the finger-like bumps 220 are gold (Au) bumps and are disposed on one side, on two corresponding sides or on peripheries of the active surface 211 of the chip 210 in a linear fashion or in a stagger fashion.

Furthermore, the dimensions of the extension fingers 222 are disposed outside the bonding pads 212 so that the finger-like bumps 220 are extended to increase effective bonding area of the finger-like bumps 220. In the present embodiment, the extended lengths of the extension fingers 222 from the bump cores 221 are not smaller than one-fourth of the lengths of the corresponding bump cores 221, preferably, not smaller than half of the lengths of the bump cores 221. The lengths of the extension fingers 222 are not greater than 150 μm so that the lengths of the finger-like bumps 220 range from 50 μm to 280 μm. Preferably, the widths of the extension fingers 222 and the bump cores 221 can be the same so that the finger-like bumps 220 have consistent appearances. As shown in FIG. 7, in the present embodiment, the chip 210 has an adjacent edge 215 where the finger-like bumps 220 are close. The extension fingers 222 corresponding to the bump cores 221 are far away from the edge 215. The extended direction of the extension fingers 222 is perpendicular to the edge 215. Therefore, the finger-like bumps 220 can be parallely disposed in high-density arrangement to achieve smaller bump pitches.

In the present embodiment, the bumped chip 200 is an LCD driver chip where the finger-like bumps 220 can be implemented in the output leads of an LCD driver chip with high densities and high-pin counts. As shown in FIG. 6, the bumped chip 200 further has a plurality of regular bumps 240 protrusively disposed on the chip 210 without extension fingers 222 so that the shapes of the regular bumps 240 are different from the ones of finger-like bumps 220. The finger-like bumps 220 are longer and narrower than the regular bumps 240. Preferably, as shown in FIG. 6, each regular bump 240 has a top surface with an area equal to the one of each finger-like bump 220. The density of the regular bumps 240 is lower than the one of the finger-like bumps 220, therefore, the bumps 240 can be implemented as the input leads of an LCD driver chip with low pin counts. In different embodiments, the shapes of the bumps 240 can be the same as the conventional bump or as the finger-like bumps 220.

The implementation of the bumped chip 200 is revealed in FIG. 8. The finger-like bumps 220 are bonded to a plurality of leads 320 of a substrate 310 where the thicknesses of the leads 320 range from 3 μm to 18 μm. Preferably, the bump cores 221 and the extension fingers 222 have the same height so that the bump cores 221 and the extension fingers 222 have a plurality of top surfaces on a same plane with a roughness less than 3 μm for bonding to the leads 320. The coplanar height of the bump cores 221 and extension fingers 222 ranges from 8 μm to 25 μm, and the width of the bump cores 221 and extension fingers 222 ranges from 8 μm to 25 μm. In the present embodiment, the bumped chip 200 can be implemented in COF where the substrate 310 is a thin film circuit. The bumped chip 200 can further be implemented in COG where the substrate 310 is a glass substrate such as an LCD panel and the leads 320 are ITO traces.

More specifically, as shown in FIGS. 5 and 8, the bumped chip 200 further comprises a Under Bump Metallurgy (UBM) layer 230 which is disposed between the finger-like bumps 220 and the passivation layer 213 and electrically connected to the bonding pads 212 via the openings 214 where the dimension of the UBM layer 230 is approximately equal to the footprints of the bump cores 221 and the extension fingers 222. Normally, the UBM 230 is formed by sputtering and is chosen from a group consisting of TiW/Au, TiW/Cu/Au, and Ti/Ni/Au.

Therefore, the bumped chip 200 according to the first embodiment of the present invention, more finger-like bumps 220 can be disposed in a limited area of a chip without affecting the bonding strengths of the bumps 220 nor causing electrical shorts between the bumps 220 of the bumped chip 200 due to fine pitches. The bumped chip 200 with finger-like bumps 220 can meet the requirements of high-density and fine-pitch bumps.

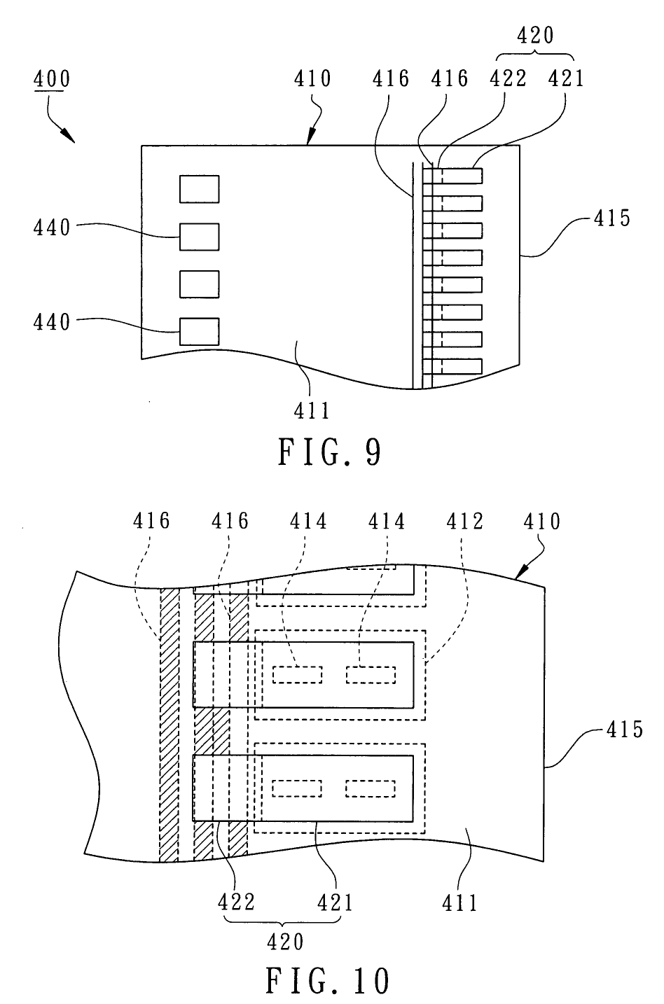

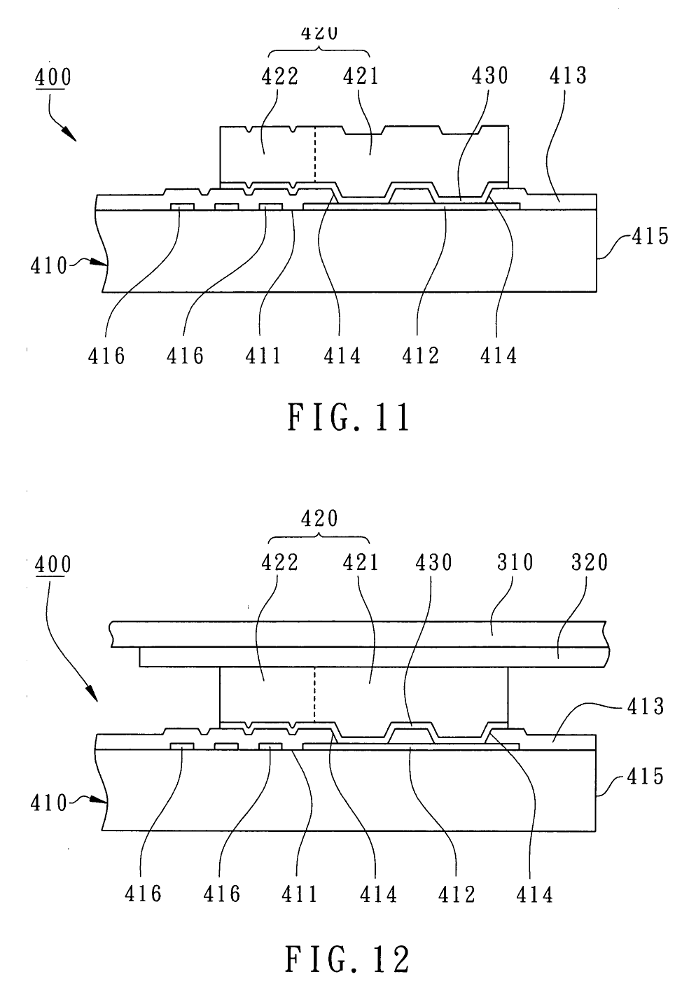

According to the second embodiment of the present invention, a bumped chip 400 with finger-like bumps bonded on multiple openings is revealed, as shown in FIGS. 9 to 12. The bumped chip 400 primarily comprises a chip 410 and a plurality of finger-like bumps 420. As shown in FIG. 11, the chip 410 has an active surface 411 and a plurality of bonding pads 412 disposed on the active surface 411 where the active surface 411 includes IC components such as memory, logic, or LCD driver circuits. The bonding pads 412 are external terminals for the IC components and are Al pads or Cu pads.

As shown in FIG. 11, the chip 410 further has a passivation layer 413 for electrical isolation such as PSC, PI or BCB with thickness not greater than 3 μm. As shown in FIGS. 10 and 11, the passivation layer 413 has a plurality of openings 414 corresponding to each bonding pad 412 where the area of the openings 414 is smaller than the one of the corresponding bonding pad 412 to partially expose the bonding pads 412. Moreover, the area of each opening 414 on each bonding pad 412 cannot be greater than 1000 μm² where the openings 414 are narrow slots and arranged linearly.

The finger-like bumps 420 are protrusively disposed on the active surface 411 of the chip 410 where each finger-like bump 420 has a bump core 421 and an extension finger 422 so that the finger-like bump 420 can be designed as parallel strips. The bump cores 421 are the portion of finger-like bumps 420 disposed on the corresponding bonding pads 412 and the extension fingers 422 are the other portion of finger-like bumps 420 extended outside the corresponding bonding pads 412. Furthermore, the materials of the finger-like bumps 420 can be gold, copper, aluminum or other conductive metals.

As shown in FIGS. 9, 10 and 11, the chip 410 has at least a trace 416 close to the bonding pads 412 where the trace 416 is covered by the passivation layer 413 and is electrically connected to the IC components inside the chip 410 or is parts of the IC components of the chip 410. In the present embodiment, the spacing between the traces 416 is not greater than 40 μm.

The extension fingers 422 pass over the trace 416. To be more specific, the extension fingers 422 of the finger-like bumps 420 can be formed above IC area of the chip 410 where some of IC components are located under the extension fingers 422. As shown in FIGS. 10 and 11, the bump cores 421 are disposed on the corresponding bonding pads 412 and the footprint of the bump cores 421 is formed within the corresponding bonding pads 412 and greater than the openings 414. Furthermore, in the present embodiment, the finger-like bumps 420 are arranged only adjacent to one edge 415 of the active surface 411 of the chip 410. However, the finger-like bumps 420 can also be arranged at two corresponding sides at peripheries of the active surface 411 of the chip 410 in a linear fashion or in a stagger fashion.

Since the extension fingers 422 extend outside the corresponding bonding pads 412 to make the finger-like bumps 420 as protrusive fingers on the active surface 411 of the chip 410 so that the effective bonding areas of the bumps 420 are increased. Normally, the length of the finger-like bumps 420 including the bump cores 421 and the extension fingers 422 are twice greater than the width of the bump cores 421. In the present embodiment, the length of the extension fingers 422 is not greater than 150 μm. The widths of the bump cores 421 and the extension fingers 422 can be the same so that the finger-like bumps 420 have consistent appearances.

As shown in FIG. 10, in the present embodiment, the active surface 411 of the chip 410 has an edge 415 where the finger-like bumps 420 are disposed adjacent in a manner that the bump cores 421 are close to the edge 415 and the extension fingers 422 far away from the edge 415. Preferably, the finger-like bumps 420 can be parallel arranged in high densities to achieve fine-pitch bumps and the extending directions of the extension fingers 422 are perpendicular to the edge 415.

Furthermore, by using the numbers and arrangement of the plurality of openings 414 on the passivation layer 413 corresponding to each bonding pad 412, the bump cores 421 of the finger-like bumps 420 are bonded to the bonding pads 412 by the multiple openings 414 to enhance the anti-cracking properties at the interfaces between the bump cores 421 and the bonding pads 412 and to reduce the roughness on the top of the bumps to increase the bonding strengths. As shown in FIG. 10, preferably, a plurality of openings 414 corresponding to each bonding pad 412 are linearly arranged where the arrangement direction is perpendicular to the edge 415.

In the present embodiment, the bumped chip 400 is a display driver chip for LCD or OLED panel and the finger-like bumps 420 are implemented as high pin counts and high densities output pins. As shown in FIG. 9 again, the bumped chip 400 further has a plurality of regular bumps 440 which are protrusively disposed on the chip 410. The footprints of regular bumps 440 are formed within the corresponding bonding pads without any extension finger extending therefrom. Therein, the arrangement density of the regular bumps 440 is smaller than the finger-like bumps 420 and is implemented as low pin counts and low densities input pins for display driver chips. In this embodiment, the shapes of the regular bumps 440 are different from the finger-like bumps 420. In another embodiment, the regular bumps 440 can be replaced by the finger-like bumps 420 (not shown in figures).

The implementation of the bumped chip 400 is revealed in FIG. 12. The finger-like bumps 420 are bonded to a plurality of leads 320 of a substrate 310. Preferably, the bump cores 421 and the extension fingers 422 have coplanar top surfaces in a same bump height ranged from 8 μm to 25 μm where the roughness on the flat top surfaces of both bump cores 421 and extension fingers 422 is controlled under 3 μm for effectively bonding to the leads 320. Furthermore, the dimensions of the width of the finger-like bumps 420 are from 8 μm to 25 μm. In the present embodiment, the bumped chip 400 can be implemented in COF packaging where the substrate 310 is a thin film circuit. However, the bumped chip 200 also can be implemented in COG device where the substrate 310 is a glass substrate such as an LCD panel and the leads 320 are ITO traces.

More specifically, as shown in FIG. 11 again, the bumped chip 400 further comprises a Under Bump Metallurgy (UBM) layer 430, disposed between the finger-like bumps 420 and the passivation layer 413 and connected to the bonding pads 412 via the openings 414 where the dimensions of the UBM layer 430 is equal to the footprints of the bump cores 421 and the extension fingers 422. Normally, the UBM layer 230 is formed by sputtering and is chosen from a group consisting of TiW/Au, TiW/Cu/Au, or Ti/Ni/Au.

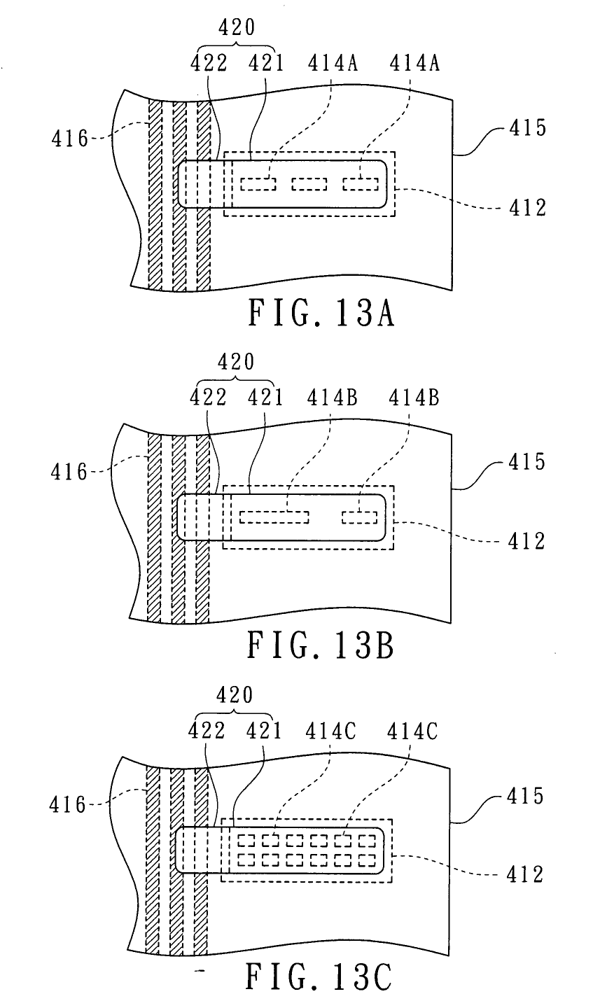

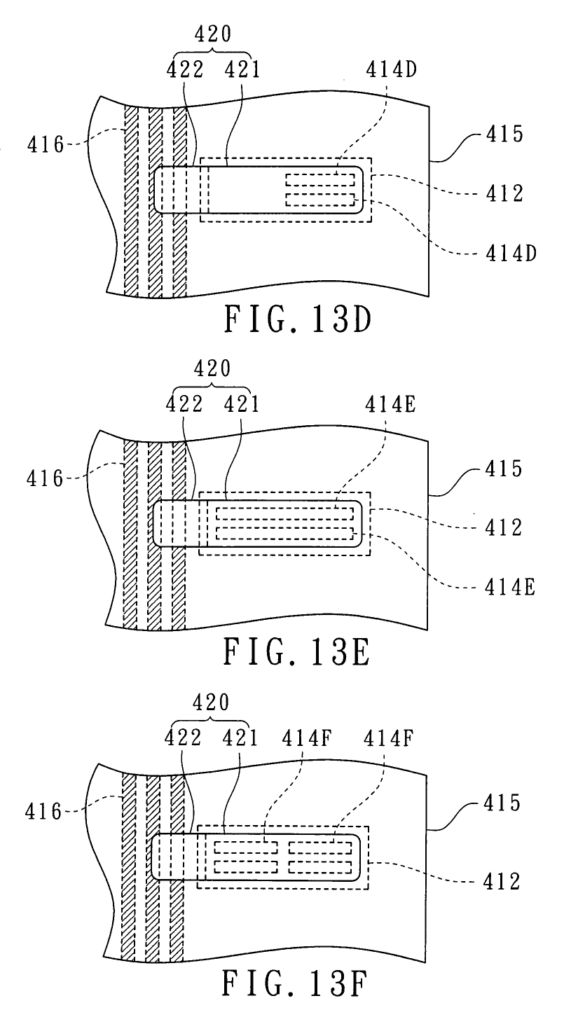

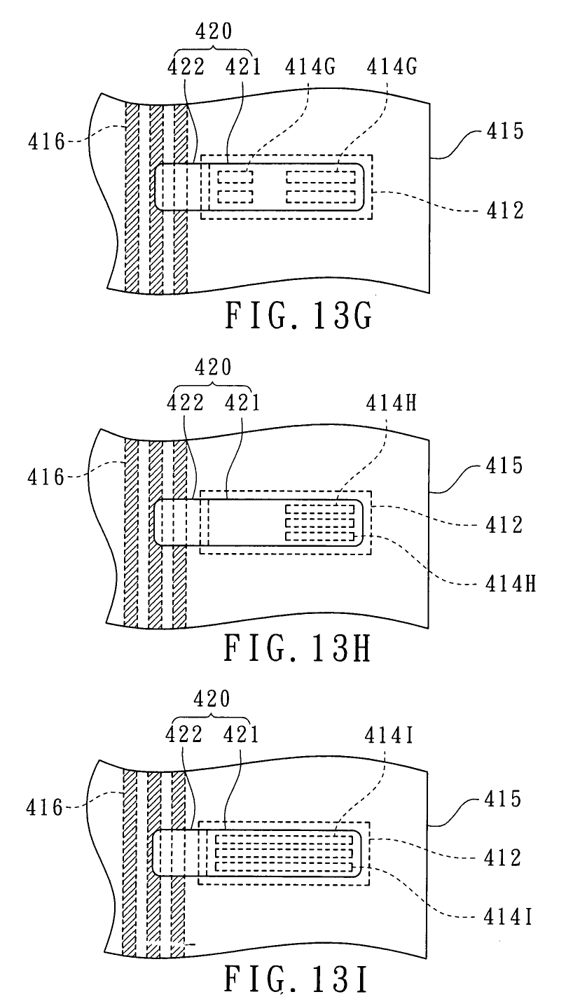

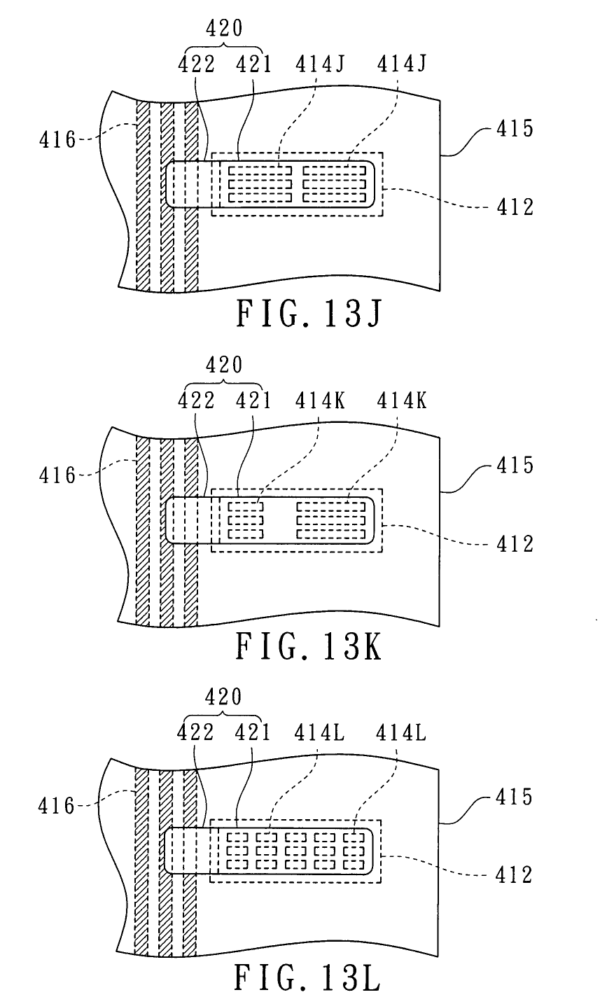

As shown in FIG. 10, the openings 414 on each bonding pad 412 have the same dimensions. However, the openings 414 on each bonding pad 412 are not limited in numbers, dimensions, locations, nor arrangements. As shown in FIG. 13A, a plurality of openings 414A on each bonding pad 412 can be increased to form more bonding points. As shown in FIG. 13B, a plurality of openings 414B on each bonding pad 412 are in different dimensions. As shown in FIG. 13C, a plurality of openings 414C on each bonding pad 412 are arranged in an array. As shown in FIG. 13D, a plurality of openings 414D on each bonding pad 412 are parallely arranged and are close to the edge 415. In different embodiments, the openings 414D on each bonding pad 412 are disposed away from the edge 415 or formed at the center of the bump core 421. As shown in FIG. 13E, a plurality of openings 414E on each bonding pad 412 are elongated and parallel to the extension fingers 422. As shown in FIG. 13F, a plurality of openings 414F on each bonding pad 412 are divided into two parallel groups. As shown in FIG. 13G, a plurality of openings 414G on each bonding pad 412 are divided into two parallel groups with different opening lengths. As shown in FIG. 13H, a plurality of openings 414H on each bonding pad 412 are arranged in multiple parallel rows. As shown in FIG. 13I, a plurality of openings 4141 on each bonding pad 412 are arranged in multiple parallel rows and are elongated and are parallel to the extension fingers 422. As shown in FIG. 13J, a plurality of openings 414J on each bonding pad 412 are divided into two groups of multiple parallel rows. As shown in FIG. 13K, a plurality of openings 414K on each bonding pad 412 are divided into two groups of multiple parallel rows with different opening dimensions. As shown in FIG. 13L, a plurality of openings 414L on each bonding pad 412 are disposed in an array and can be divided into several multiple parallel rows.

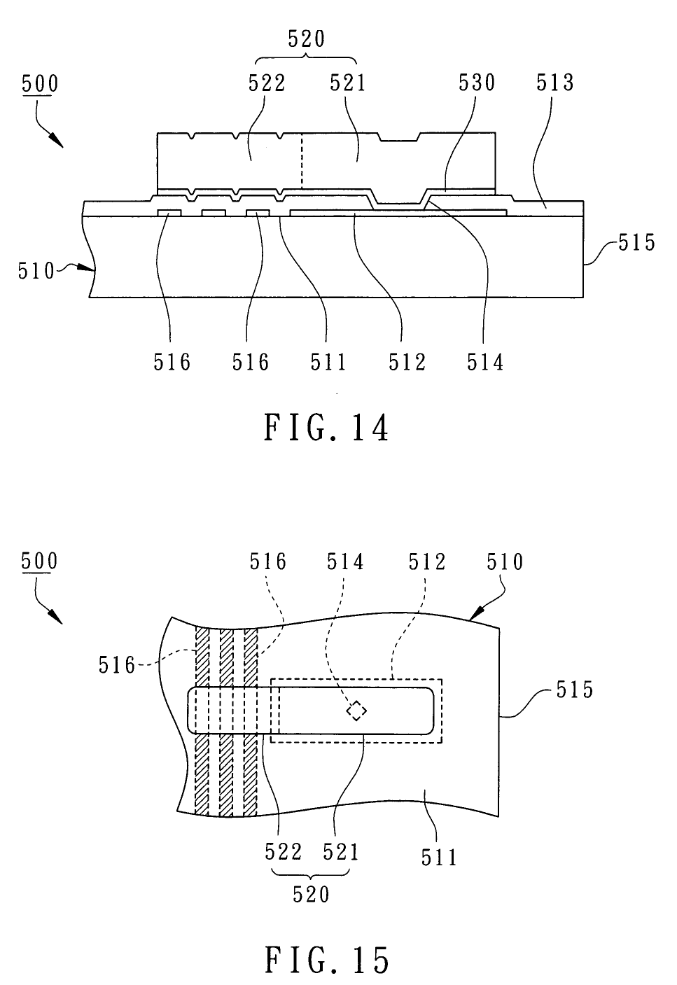

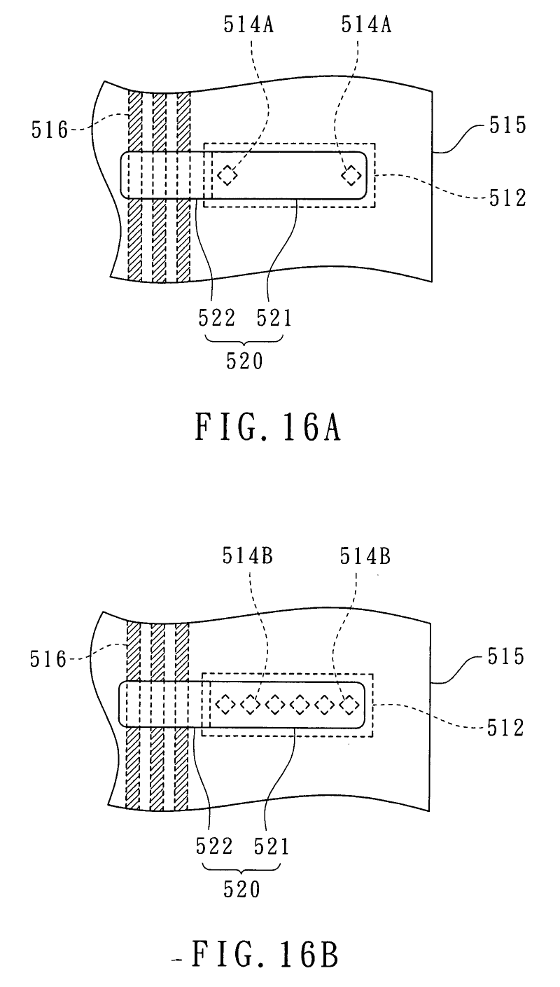

In the third embodiment, another bumped chip with finger-like bumps bonded on multiple openings is revealed. As shown in FIGS. 14 and 15, the bumped chip 500 primarily comprises a chip 510 and a plurality of finger-like bumps 520. The chip 510 has an active surface 511, a plurality of bonding pads 512, and a passivation layer 513 where the bonding pads 512 are disposed on the active surface 511. The passivation layer 513 has at least an opening 514 on each bonding pad 512. The dimension of the opening 514 on each bonding pad 512 is smaller than the one of the corresponding bonding pad 512 to partially expose the bonding pad 512. As shown in FIG. 15 again, in the present embodiment, the openings 514 can be rhombuses or rectangles. However, in the present invention, the numbers and locations of the openings 514 on the passivation layer 513 are not limited. As shown in FIG. 16A, a plurality of openings 514A on each bonding pads 512 are located on two opposing sides of the bonding pad 512. As shown in FIG. 16B, a plurality of openings 514B are disposed and are linearly arranged on the corresponding bonding pad 512.

As shown in FIGS. 14 and 15 again, the finger-like bumps 520 are protrusively disposed on the active surface 511 of the chip 510 where each finger-like bump 520 has a bump core 521 and an extension finger 522. The bump cores 521 are disposed on the corresponding bonding pads 512 and are larger than the openings 514. The extension fingers 522 are extended outside the corresponding bonding pads 512. In this embodiment, the chip 510 further has at least a trace 516 close to the bonding pads 512, where the trace 516 is covered by the passivation layer 513 and overlapped under the extension finger 522. As shown in FIG. 15, the active surface 511 of the chip 510 has an edge 515 where the finger-like bumps 520 are adjacent to. The extension fingers 522 are far away from the edge 515 corresponding to the bump cores 521.

More specifically, the bumped chip 500 further comprises a UBM layer 530 disposed between the finger-like bumps 520 and the passivation layer 513 and connected to the bonding pads 512 via the openings 514 where the dimension of the UBM layer 530 is equal to the footprints of the bump cores 521 and the extension fingers 522.

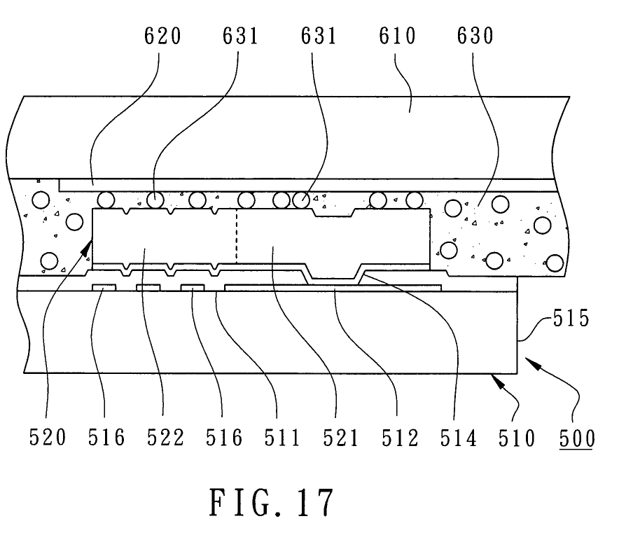

The implementation of the bumped chip 500 is revealed in FIG. 17. An antisotropic conductive film (ACF) 630 is disposed between the bumped chip 500 and a substrate 610 where the ACF 630 has conductive particles 631 with the same diameters evenly distributed in the ACF 630. The finger-like bumps 520 are electrically connected to a plurality of leads 620 on the substrate 610 by the conductive particles 631 in the ACF 630. The substrate 610 is a glass substrate and the leads 620 are ITO traces so that the bumped chip 500 can be implemented in COG products.

The above description of embodiments of this invention is intended to be illustrative and not limiting. Other embodiments of this invention will be obvious to those skilled in the art in view of the above disclosure.

What is claimed is:

1. A bumped chip comprising:
a chip having an active surface, a plurality of bonding pads and a passivation layer, wherein the bonding pads are disposed on the active surface and the passivation layer has at least an opening corresponding to each of the bonding pads and the total dimension of the openings on each bonding pad is smaller than the one of the corresponding bonding pads to partially expose the bonding pads; and
a plurality of finger-like bumps protrusively disposed on the active surface of the chip, each finger-like bump having a bump core and an extension finger, wherein the footprints of the bump cores are disposed within the corresponding bonding pads and are larger than the openings, wherein the footprints of the extension fingers are disposed outside the corresponding bonding pads.

2. The bumped chip of claim 1, wherein the openings are narrow slots.

3. The bumped chip of claim 1, wherein the area of each opening is not greater than 1000 μm².

4. The bumped chip of claim 1, wherein the openings on each bonding pad are plural and parallely disposed.

5. The bumped chip of claim 1, wherein the openings on each bonding pad are plural and linearly disposed.

6. The bumped chip of claim 1, wherein the openings on each bonding pad are plural and disposed in an array.

7. The bumped chip of claim 1, wherein the thickness of the passivation layer is not greater than 2 μm.

8. The bumped chip of claim 1, wherein the bump cores and the extension fingers have a plurality of top surfaces on a same plane with a roughness less than 3 μm.

9. The bumped chip of claim 8, wherein the coplanar height of the finger-like bumps ranges from 8 μm to 25 μm, and the width of the finger-like bumps ranges from 8 μm to 25 μm.

10. The bumped chip of claim 1, wherein the extension fingers have a length from the bump cores not greater than 150 μm.

11. The bumped chip of claim 1, wherein the extension fingers extend far away from an adjacent edge of the active surface of the chip to the finger-like bumps.

12. The bumped chip of claim 11, wherein the extending directions of the extension fingers are perpendicular to the edge.

13. The bumped chip of claim 1, wherein the bump cores and the extension fingers have a same width.

14. The bumped chip of claim 1, further comprising a UBM layer disposed between the finger-like bumps and the passivation layer and bonded to the bonding pads via the openings, wherein the UBM layer has a dimension equal to the footprints of the bump cores and the extension fingers.

15. The bumped chip of claim 1, wherein the bonding pads are aluminum (Al) pads and the finger-like bumps are gold (Au) bumps.

16. The bumped chip of claim 1, wherein the finger-like bumps contain a material chosen from a group consisting of gold, copper and aluminum.

17. The bumped chip of claim 1, further comprising a plurality of regular bumps protrusively disposed on the active surface of the chip and having a shape different from the finger-like bumps.

18. A bumped chip comprising:
a chip having an active surface, a plurality of bonding pads and a passivation layer wherein the bonding pads are disposed on the active surface and the passivation layer has at least an opening corresponding to each of the bonding pads, the area of each opening is smaller than the one of the corresponding bonding pad to partially expose the bonding pads; and
a plurality of finger-like bumps protrusively disposed on the active surface of the chip, each finger-like bump having a bump core and an extension finger, wherein the footprints of the bump cores are disposed within the corresponding bonding pads and are larger than the openings, wherein the footprints of the extension fingers are disposed outside the corresponding bonding pads;
wherein the chip further has at least a trace adjacent to the bonding pads, wherein the trace is covered by the passivation layer and is overlapped under the extension fingers.

19. The bumped chip of claim 18, wherein the openings are rhombuses or rectangles.

20. The bumped chip of claim 18, wherein the area of each opening is not greater than 1000 μm².

21. The bumped chip of claim 18, wherein the openings on each bonding pad are plural and linearly disposed.

22. The bumped chip of claim 18, wherein the thickness of the passivation layer is not greater than 2 μm.

23. The bumped chip of claim 18, wherein the bump cores and the extension fingers have a plurality of top surfaces on a same plane with a roughness less than 3 μm.

24. The bumped chip of claim 23, wherein the coplanar height of the finger-like bumps ranges from 8 μm to 25 μm, and the width of the finger-like bumps ranges from 8 μm to 25 μm.

25. The bumped chip of claim 18, wherein the extension fingers have a length from the bump cores not greater than 150 μm.

26. The bumped chip of claim 18, wherein the extension fingers extend far away from an adjacent edge of the active surface of the chip to the finger-like bumps.

27. The bumped chip of claim 26, wherein the extending directions of the extension fingers are perpendicular to the edge.

28. The bumped chip of claim 18, wherein the bump cores and the extension fingers have a same width.

29. The bumped chip of claim 18, further comprising a UBM layer disposed between the finger-like bumps and the passivation layer and bonded to the bonding pads via the openings, wherein the UBM layer has a dimension equal to the footprints of the bump cores and the extension fingers.

30. The bumped chip of claim 18, further comprising a plurality of regular bumps protrusively disposed on the active surface of the chip and having a shape different from the finger-like bumps.

31. The bumped chip of claim 30, wherein each regular bump has a top surface with an area equal to the one of each finger-like bump.

32. The bumped chip of claim 18, wherein the length of bump cores is not greater than 150 μm.
